(19) United States
(12) Patent Application Publication
(10) Pub. No.: US 2023/0052297 A1
(43) Pub. Date: Feb. 16, 2023

(54) Systems and Methods to Emulate a Sensor in a Vehicle

(71) Applicant: Ford Global Technologies, LLC, Dearborn, MI (US)

(72) Inventors: Ayush Chandrakanth Shah, Belleville, MI (US); Nithya Somanath, Farmington Hills, MI (US); Joseph Wisniewski, Royal Oak, MI (US); Harald Christian Martinez, Northville, MI (US); Jeffrey Brian Yeung, Canton, MI (US)

(21) Appl. No.: 17/402,180

(22) Filed: Aug. 13, 2021

(51) Int. Cl. G06F 30/20; G07C 5/00; G06N 20/00

(52) U.S. Cl. CPC G06F 30/20; G07C 5/008; G06N 20/00

(57) ABSTRACT

This disclosure is generally directed to systems and methods for providing a software sensor in a vehicle. In an example embodiment, a determination is made regarding the availability of a feature upgrade to a vehicle and a request may be made (to a cloud computer, for example), for obtaining the feature upgrade. The cloud computer provides an emulation software module based on emulating a first sensor that is unavailable in the vehicle. The feature upgrade may be installed in the vehicle by executing the emulation software module and by use of a second sensor that is available in the vehicle. In an example implementation, the second sensor available in the vehicle is a type of hardware sensor such as, for example, a camera, and the first sensor that is emulated is a different type of hardware sensor such as, for example, an air quality sensor.

### BACKGROUND

An automobile dealership typically sets a price for a vehicle based on various optional features provided in the vehicle. Thus, a vehicle having a basic set of features may be priced lower than the same model vehicle having a more sophisticated set of features. The more sophisticated set of features may include items such as, for example, an intelligent infotainment system, a back-up camera, an object detection system, a keyless operation system, and a security system.

A first customer may decide to buy the vehicle having the basic set of features rather than spend additional money on features that he/she deems unnecessary. The first customer may suffer from buyer's remorse later on and may wish that he/she had at least some of the items that were offered in the higher priced vehicle. On the other hand, a second customer may purchase the higher priced vehicle only to discover later on, that some of the items present in the higher priced vehicle have turned obsolete.

It is therefore desirable to provide a solution that addresses scenarios such as the ones described above.

### BRIEF DESCRIPTION OF THE DRAWINGS

A detailed description is set forth below with reference to the accompanying drawings. The use of the same reference numerals may indicate similar or identical items. Various embodiments may utilize elements and/or components other than those illustrated in the drawings, and some elements and/or components may not be present in various embodiments. Elements and/or components in the figures are not necessarily drawn to scale. Throughout this disclosure, depending on the context, singular and plural terminology may be used interchangeably.

FIG. 1 illustrates a first example scenario where an emulation software module is downloaded into a vehicle in accordance with an embodiment of the disclosure.

FIG. 2 illustrates a second example scenario where an emulation software module is downloaded into a vehicle in accordance with an embodiment of the disclosure.

FIG. 3 illustrates a third example scenario where an emulation software module is downloaded into a vehicle in accordance with an embodiment of the disclosure.

FIG. 4 shows an example scenario where a vehicle performs air quality monitoring operations in accordance with an embodiment of the disclosure.

FIG. 5 shows another example scenario where a vehicle performs air quality monitoring operations in accordance with an embodiment of the disclosure.

FIG. 6 shows yet another example scenario where a vehicle performs air quality monitoring operations in accordance with an embodiment of the disclosure.

FIG. 7 shows an example scenario where a vehicle utilizes an automatic braking system in accordance with an embodiment of the disclosure.

FIG. 8 shows some example components that may be provided in a vehicle in accordance with an embodiment of the disclosure.

### DETAILED DESCRIPTION

The disclosure will be described more fully hereinafter with reference to the accompanying drawings, in which example embodiments of the disclosure are shown. This disclosure may, however, be embodied in many different forms and should not be construed as limited to the example embodiments set forth herein. It will be apparent to persons skilled in the relevant art that various changes in form and detail can be made to various embodiments without departing from the spirit and scope of the present disclosure. Thus, the breadth and scope of the present disclosure should not be limited by any of the above-described example embodiments but should be defined only in accordance with the following claims and their equivalents. The description below has been presented for the purposes of illustration and is not intended to be exhaustive or to be limited to the precise form disclosed. It should be understood that alternate implementations may be used in any combination desired to form additional hybrid implementations of the present disclosure. For example, any of the functionality described with respect to a particular device or component may be performed by another device or component. Furthermore, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments.

Certain words, terms, and phrases that are used in this disclosure must be interpreted as referring to various objects and actions that are generally understood in various forms and equivalencies by persons of ordinary skill in the art. For example, the word “software” as used herein encompasses any of various forms of computer code and may be provided in various forms such as in the form of a software package, a firmware package, retail software, or Original Equipment Manufacturer (OEM) software. The word “sensor” as used herein includes any of various forms of detection and/or measuring devices used for carrying out operations such as detecting objects located inside and/or outside a vehicle, capturing images inside and/or outside the vehicle, detecting sounds inside and/or outside the vehicle, receiving wireless signals, and/or measuring parameters such as, for example, distances, sound, feature status (e.g., is a door or a hood of the vehicle open), temperature, pollutants inside or outside the vehicle, intensities, amplitudes, brightness, and moisture. The word “example” as used herein is intended to be non-exclusionary and non-limiting in nature.

In terms of a general overview, certain embodiments described in this disclosure are directed to systems and methods related for providing a software sensor in a vehicle. In an example embodiment, a determination is made regarding the availability of a feature upgrade to a vehicle and a request may be made (to a cloud computer, for example), for obtaining the feature upgrade. The cloud computer provides an emulation software module based on emulating a first sensor that is unavailable in the vehicle. The feature upgrade may be installed in the vehicle by executing the emulation software module and by use of a second sensor that is available in the vehicle. In an example implementation, the second sensor available in the vehicle is a type of hardware sensor such as, for example, a camera, and the first sensor that is emulated is a different type of hardware sensor such as, for example, an air quality sensor. The air quality sensor may not be present in a vehicle either because the sensor was an optional device that was declined during purchase of the vehicle or was intentionally omitted during manufacture of the vehicle. The air quality sensor may be omitted during manufacture for various reasons such as, for example, because the functionality of the air quality sensor was provided by use of a multifunction device.

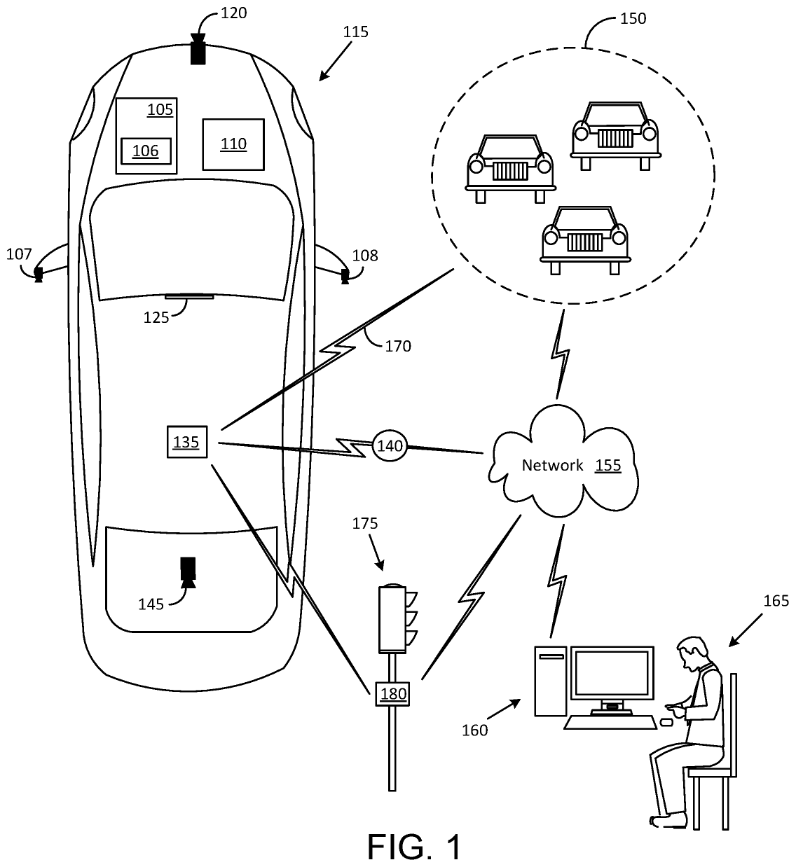

FIG. 1 illustrates a first example scenario where an emulation software module 140 is downloaded into a vehicle 115 in accordance with an embodiment of the disclosure. The vehicle 115 may be any of various types of vehicles such as, for example, a gasoline powered vehicle, an electric vehicle, a hybrid electric vehicle, or an autonomous vehicle, a car, a sports utility vehicle (SUV), a truck, a van, a semi-trailer truck, a bus, or an autonomous vehicle. In some implementations, the description provided herein may be equally applicable to other types of vehicles such as, for example, an aircraft, an unmanned aerial vehicle (UAV), a robotic vehicle (delivery robot, for example), and a water craft (boat, ship, robotic vessel, etc.). The vehicle 115 may include components such as a vehicle computer 110, an infotainment system 125, a communication system 135, a sensor management system 105, and various sensors such as, for example, a camera 120, a camera 145, a camera 107, and a camera 108.

The vehicle computer 110 may perform various functions such as controlling engine operations (fuel injection, speed control, emissions control, braking, etc.), managing climate controls (air conditioning, heating etc.), activating airbags, and issuing warnings (check engine light, bulb failure, low tire pressure, vehicle in blind spot, etc.). In some cases, the vehicle computer 110 may include more than one computer such as, for example, a first computer that controls engine operations and a second computer that operates the infotainment system 125.

The sensor management system 105 can include a computer having a processor and a memory in which is stored computer-executable instructions that are executed by the processor to enable the computer to perform various operations in accordance with the disclosure. In an example implementation, the sensor management system 105 can include a standalone computer that is communicatively coupled to the vehicle computer 110 and other devices in the vehicle 115. In another example implementation, the sensor management system 105 can be a part of the vehicle computer 110 and share some components with the vehicle computer 110, such as, for example a processor and a memory.

The sensor management system 105 may be coupled to various hardware sensors provided in the vehicle 115. The sensors can include devices such as, for example, a video camera, a digital camera, an infrared camera, an object detector, a distance sensor, a proximity sensor, an air quality sensor, a sun load sensor, an audio sensor, a light detection and ranging (LIDAR) device, a radar device, and/or a sonar device. In the illustrated example, the sensor management system 105 is communicatively coupled to the camera 120, the camera 145, the camera 107, and the camera 108. In other cases, the sensor management system 105 may be communicatively coupled to various other types of sensors and detectors.

The camera 120, which can be any of various types of image capture devices, may be mounted on a front bumper, side mirror, roof pillar, or roof of the vehicle 115 and arranged to capture images of objects ahead of the vehicle 115. The images may be still pictures, video clips, or video streams, for example. The camera 145, which can be similar to camera 120, may be mounted on a rear bumper, rear window, roof pillar, roof, or trunk of the vehicle 115 and arranged to capture images of objects behind the vehicle 115. The camera 107, which can be any of various types of image capture devices, may be mounted on a driver-side mirror assembly of the vehicle 115 and arranged to capture images of objects to the left side of the vehicle 115. The camera 108, which can be similar to the camera 107, may be mounted on a passenger-side mirror assembly of the vehicle 115 and arranged to capture images of objects to the right side of the vehicle 115.

The infotainment system 125 can be an integrated unit that includes various components such as a radio, a CD player, and a video player. In an example implementation, the infotainment system 125 has a display that includes a graphical user interface (GUI) for use by an occupant of the vehicle 115. The GUI may be used for various purposes including, for example, to input destination information for obtaining navigation assistance. The navigation assistance may be obtained via signals provided by a global positioning system (GPS) device coupled to the infotainment system 125.

The communication system 135 can include wired and/or wireless communication devices mounted in or on the vehicle 115 in a manner that support various types of communications such as, for example, communications between the sensor management system 105 and the vehicle computer 110. The communication system 135 may utilize one or more of various wired and/or wireless technologies for this purpose, such as, for example, Bluetooth®, Ultra-Wideband (UWB), Wi-Fi, Zigbee®, Li-Fi (light-based communication), audible communication, ultrasonic communication, and/or near-field-communications (NFC).

The sensor management system 105 and the vehicle computer 110 can also utilize the communication system 135 to communicate with devices that may be located outside the vehicle 115, such as, for example, computers located in other vehicles (the vehicles are illustrated inside a dashed circle 150) and a computer 160. Such communications may be carried out directly with each other and/or via a network 155. Communications carried out directly between vehicles may be carried out by using communications technologies such as WiFi and vehicle-to-vehicle (V2V) communications (as illustrated by a communication link 170).

The network 155 may include any one network, or a combination of networks, such as, for example, a local area network (LAN), a wide area network (WAN), a telephone network, a cellular network, a cable network, a wireless network, and/or private/public networks such as the Internet. The network 155 may support one or more types of communication technologies such as, for example, Bluetooth®, Ultra-Wideband, cellular, near-field communication (NFC), Wi-Fi, Wi-Fi direct, Li-Fi, vehicle-to-vehicle (V2V) communications, infrastructure-to-vehicle (I2V) communications, vehicle-to-infrastructure (V2I) communications, and vehicle-to-everything (V2X) communications. An example V2I is illustrated in the form of a traffic light 175 that includes a V2I wireless communication unit 180.

In various implementations, the computer 160 can be a server computer, a cloud computer, or a client computer. In one implementation, the computer 160 is configured to perform various actions in accordance with disclosure such as, for example, making a determination that the vehicle 115 lacks a certain type of sensor, creating a software sensor based on emulating information obtained from computers of various vehicles, and/or transferring an emulation software module to the vehicle 115.

In an example scenario, the vehicle 115 may be equipped during manufacture, or during sale of the vehicle 115, by devices such as, for example, the camera 120, the camera 145, the camera 107, and the camera 108. The camera 120 may be used for capturing images of objects in front of the vehicle 115 and the images may be used, for example, by an insurance agent to examine and obtain details pertaining to an accident where the vehicle 115 may have collided with an object. The camera 145 may be configured to operate as a back-up camera that captures and propagates images of the rear view of the vehicle 115 to the infotainment system 125. A driver of the vehicle 115 may observe these images when moving the vehicle 115 in reverse so as to avoid colliding with obstacles, if present, in the path of the vehicle 115. The camera 107 and the camera 108 may be components of a blind spot information system that may be used by the driver of the vehicle 115. The images provided by the camera 120, the camera 145, the camera 107, and/or the camera 108 may be independent of each other. For example, the images provided by the camera 145 may be used independent of images provided by the other cameras and would be typically only during certain times (when the vehicle 115 is moving in reverse). An image provided by the camera 108 may only be observed when the driver wishes to switch lanes, for example, and ensure that there is no other vehicle present in his/her blind spot.

Sometime later (a couple of years, for example), the dealer who sold the vehicle 115 to the vehicle owner may contact the owner to inform the owner of a feature upgrade that is available in the form of a 360° view display option that was hitherto unavailable in the vehicle 115. The feature upgrade may be available to the owner via execution of an emulation software module 140 that can be downloaded into the sensor management system 105 from the computer 160. The feature upgrade may stitch together images provided by the camera 120, the camera 145, the camera 107, and the camera 108 and produce a 360° view that is displayed on the infotainment system 125 and allows the driver to see objects all around the vehicle 115 at all times. The owner may submit a purchase order to purchase the feature upgrade (either through a one-time transaction or through a subscription service that allows him/her to acquire this feature and/or other features, as and when desired). Consequently, the vehicle 115 that may be deemed a base model during manufacture or sale and lacks certain features can be upgraded to a premium model vehicle, by adding one or more features effected by the emulation software module 140.

In an example procedure, the computer 160 (a server computer, a cloud computer, a client computer etc.) may be used to fulfil the purchase order by wirelessly sending the emulation software module 140 via the communication system 135, to a computer 106 that is a part of the sensor management system 105. The emulation software module 140 may be sent via any of various ways such as, for example, through the network 155, directly through the communication link 170, and/or via the network 155 and the wireless communication unit 180 that is mounted on the traffic light 175.

In accordance with the disclosure, the emulation software module 140 may be created by obtaining information from various computers located in various vehicles (the vehicles are illustrated inside a dashed circle 150) and processing the information by using various techniques such as, for example, artificial intelligence (AI) and machine learning data models. Information received from the various computers may include structured data and/or unstructured data. Structured data can include, for example, sensor data, engine load, acceleration paddle position, and brake torque. Unstructured data can include, for example, camera video feed, LIDAR feed, and audio feed.

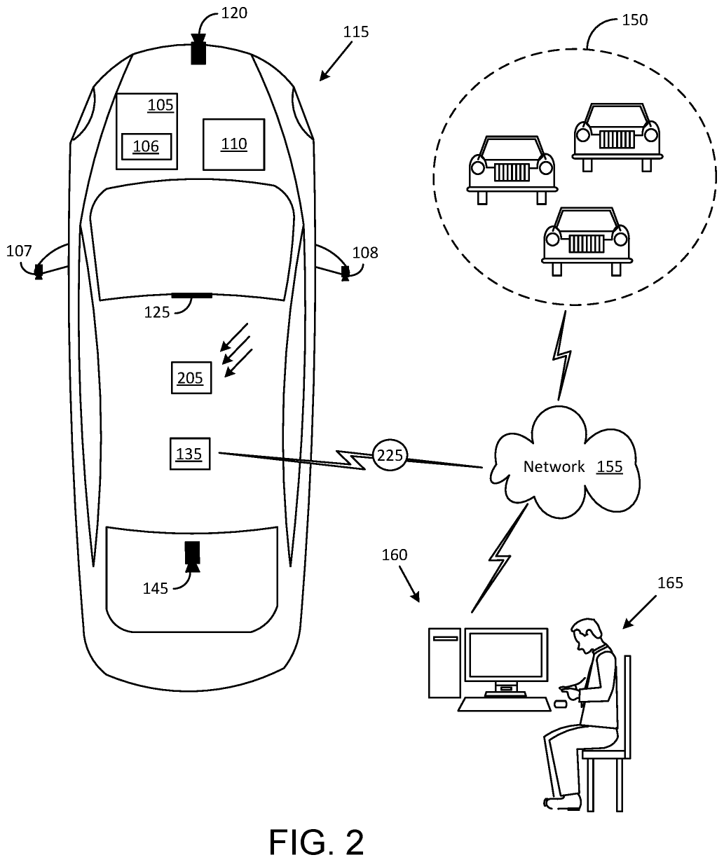

FIG. 2 illustrates a second example scenario where an emulation software module 225 is downloaded into a vehicle 115 in accordance with an embodiment of the disclosure. In this example scenario, the vehicle 115 may be equipped during manufacture, or during sale of the vehicle 115, with devices such as, for example, the camera 120, the camera 145, the camera 107, the camera 108, and a sun load sensor 205.

The sun load sensor 205 may be placed at any of various locations on an external surface of the vehicle 115 or inside in the cabin area of the vehicle 115. The sun load sensor 205, which may include a transducer that produces an electrical signal in response to sunlight falling upon the sun load sensor 205, is arranged to monitor an intensity of sunlight and to communicate the information to the sensor management system 105. The sensor management system 105 may evaluate the information and perform actions to cater to the comfort of occupants of the vehicle 115, such as, for example, adjusting a climate control system (air conditioning, heating, etc.), adjusting fan speed, and/or adjusting air vents.

Sometime later (a couple of years, for example), the dealer who sold the vehicle 115 to the vehicle owner may contact the owner to inform the owner of a feature upgrade that allows the climate control system to be operated in a more sophisticated manner (such as, for example, without manual intervention) and also offers several new functional settings. The feature upgrade may be carried out by executing an emulation software module 225 that is downloadable into the sensor management system 105 from the computer 160. The emulation software module 225 may derive sun load information by combining information obtained from images captured by one or more of the cameras with location information obtained from a GPS device in the vehicle 115. The sun load information may then be used by the sensor management system 105 to automatically execute various control functions upon the climate control system of the vehicle 115.

In another example scenario, the sun load sensor 205 that was installed in the vehicle 115 during manufacture or sale of the vehicle 115 may become defective some years later and the owner of the vehicle 115 may contact the dealer to obtain a replacement unit. The dealer may, at this time, inform the owner that it can be beneficial to replace the functionality of the sun load sensor 205 with that provided by the emulation software module 225 in order to not only save on costs associated with the purchase and installation of new hardware (a replacement sun load sensor 205) but also in terms of obtaining new features associated with climate control system of the vehicle 115. The owner may then opt to download the emulation software module 225 from the computer 160 and into the sensor management system 105 if he/she so desires.

In another example scenario, the sun load sensor 205, or a different type of sensor, that was installed in the vehicle 115 during manufacture or sale of the vehicle 115 may become defective and the owner of the vehicle 115 may contact the dealer to have the sensor repaired or replaced. The dealer may recommend a replacement of the sensor and inform the owner of a temporary fix while waiting for a replacement sensor that has been back-ordered. The temporary fix, in the form of a downloadable emulation software module, may provide at least some of the features offered by the defective sensor.

In yet another example scenario, the vehicle 115 may, during manufacture or sale, lack certain features such as, for example, a front collision warning system and/or an icy road condition detection system. Sometime later, the dealer who sold the vehicle 115 to the owner may contact the owner to inform the owner that these features can be provided on the vehicle 115 via a downloadable emulation software module. In this example scenario, the sensor management system 105 executes a downloaded emulation software module that may provide a front collision warning system and/or an icy road condition detection system based on evaluating images captured by the camera 120.

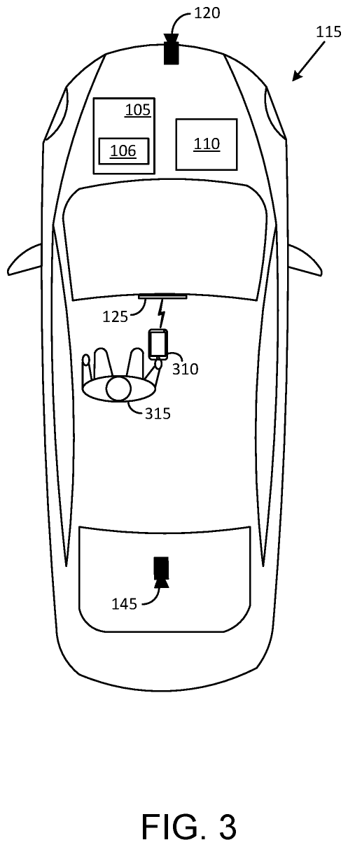

FIG. 3 illustrates a third example scenario where an emulation software module 225 is downloaded into the sensor management system 105 of the vehicle 115 in accordance with an embodiment of the disclosure. In this example scenario, an individual 315 operates a personal communication device 310, which can be any of various devices such as, for example, a smartphone, a tablet computer, a laptop computer, or a wearable device (smartwatch, for example). The computer 160 may transmit feature upgrade information to the sensor management system 105 of the vehicle 115 and/or the personal communication device 310. The information may be displayed at various times such as, for example, when a new feature becomes available and/or when a determination is made that the vehicle 115 lacks a particular feature.

In an example implementation, the determination that the vehicle 115 lacks a particular feature may be made by execution of an inventorying procedure by the sensor management system 105. The inventorying procedure may involve communications between the sensor management system 105 and the vehicle computer 110 for obtaining vehicle-related information from the vehicle computer 110. The sensor management system 105 may compare a list of features present in the vehicle 115 against a reference list of available features that may be provided to the sensor management system 105 by the computer 160.

The feature upgrade information displayed on the infotainment system 125 and/or the personal communication device 310 in a format that allows the individual 315 to purchase or subscribe to a feature upgrade and/or to enroll in a subscription service for obtaining the feature upgrade. The purchase (or enrollment) may be made via a graphical user interface (GUI) provided in the infotainment system 125 or via a software application provided in the personal communication device 310.

The computer 160 may fulfill an order by transmitting the emulation software module 140 to the sensor management system 105 and/or the personal communication device 310 via any of various ways such as, for example, through the network 155, directly through the communication link 170, and/or via the network 155 and the wireless communication unit 180 that is mounted on the traffic light 175. When sent to the personal communication device 310, the emulation software module 140 may be uploaded into the sensor management system 105 via wireless communications (Bluetooth®, Ultra-Wideband (UWB), Wi-Fi, Zigbee®, NFC. etc.) or via direct plug-in (via a USB socket on the infotainment system 125, for example).

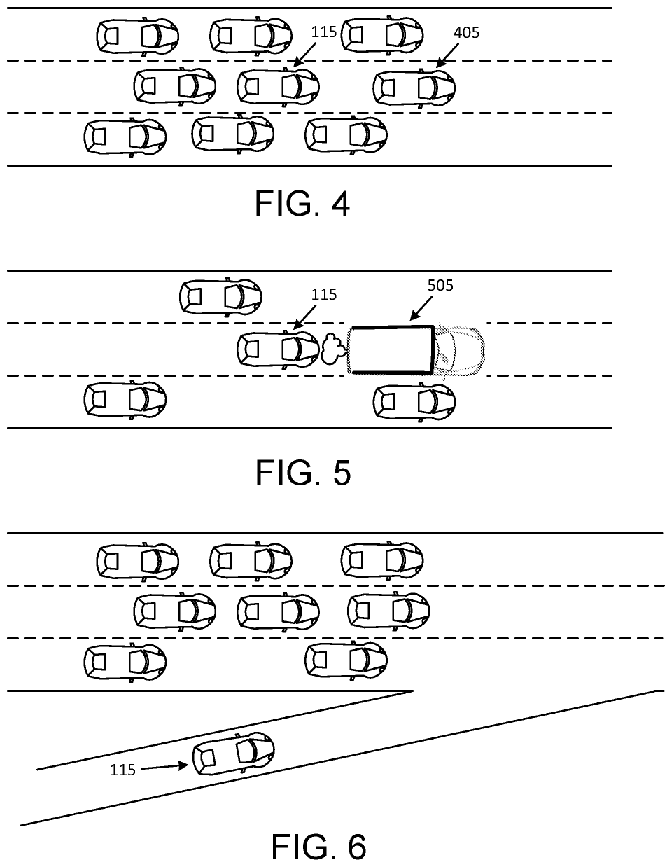

FIG. 4 shows a first example scenario where information is obtained by the computer 160 for generating emulation software in accordance with an embodiment of the disclosure. In this example scenario, the vehicle 115 is traveling on a multi-lane highway and is surrounded by a number of vehicles. Traffic movement is stop-and-go at times and stopped at other times. Some or all of the vehicles around the vehicle 115 may have air quality sensors, such as, for example, a particulate matter (PM) air quality sensor. The vehicles may transfer air quality information via the network 155 to cloud storage, and the computer 160 may retrieve this information in real-time. The vehicle 115 does not have an air quality sensor (maybe because the owner of the vehicle 115 opted not to buy one during purchase of the vehicle 115). In accordance with the disclosure, the computer 160 may generate an air quality emulation software module based on the information provided by the various vehicles and then execute the air quality emulation software module in the vehicle 115. In an example case, execution of the air quality emulation software module in the vehicle 115 may allow the vehicle 115 to, in turn, generate and share air quality information with other vehicles (via the network 155, the cloud storage, and the computer 160).

The information obtained from the other vehicle and/or generated by the vehicle 115, can include, for example, air quality measurement, location information, traffic characteristics (stopped, slow moving, stop-and-go, etc.), information about neighboring vehicles (a truck spewing smoke, an electric vehicle, etc.), weather information, surrounding infrastructure information (city, open space, etc.), and/or a real time pollution map obtained from navigation providers.

The computer 160 may provide the air quality emulation software module to the computer 106 of the sensor management system 105, in response to a request for a feature upgrade in the form of air quality monitoring. The sensor management system 105 may execute the air quality emulation software module to provide an air quality monitoring system in the vehicle 115 without necessitating the installation of a hardware air quality sensor in the vehicle 115. The air quality monitoring system may instead use sensors such as, for example, the camera 120 and the camera 145, to monitor air quality in lieu of using a hardware air quality sensor. Images captured by the camera 120 and/or the camera 145 may be evaluated by the sensor management system 105 to determine air quality based on, for example, the presence of smog or exhaust smoke outside the vehicle 115.

In a second example scenario in accordance with the disclosure, the sensor management system 105 may use the air quality emulation software module to perform air quality monitoring operations based on real-time information received from computers located in other vehicles in the vicinity of the vehicle 115. The real-time information received from the other vehicles, such as, for example, from a computer provided in the vehicle 405 that is traveling ahead of the vehicle 115, may be used by the sensor management system 105 to dynamically control the air quality in the cabin area of the vehicle 115. In an example scenario, the sensor management system 105 may close the air intake vents when the air quality is below a threshold value and may re-open the air intake vents when the air quality has subsequently improved, for example, as a result of an increase in a vehicle-to-vehicle separation distance between the vehicle 115 and the vehicle 405. The threshold value may be set by various entities. In one case, the owner of the vehicle 115 may have conveyed the threshold value information to the individual 165 who operates the computer 160.

FIG. 5 shows a third example scenario where the sensor management system 105 may use the air quality emulation software module to perform air quality monitoring operations based on real-time information received from computers located in other vehicles in the vicinity of the vehicle 115. In this example scenario, the vehicle 115 is traveling behind a truck 505 that is spewing out a large amount of exhaust, some of which may be entering the engine compartment of the vehicle 115. The sensor management system 105 may execute the air quality emulation software module and use sensors such as the camera 120 and/or the camera 145 to operate various hardware elements in the vehicle 115 (such as, for example, closing air intake vents and/or activating air-recirculation). In some cases, the sensor management system 105 may perform these operations based on real-time information received from computers located in other vehicles in the vicinity of the vehicle 115. The sensor management system 105 may re-open the air intake vents when the vehicle-to-vehicle separation distance between the vehicle 115 and the truck 505 has increased, or after the truck 505 has changed into a different traffic lane. The vehicle-to-vehicle separation distance between the vehicle 115 and the truck 505 may be determined by the sensor management system 105 based on evaluating images captured by the camera 120 (facing forwards).

FIG. 6 shows a fourth example scenario where the sensor management system 105 may use the air quality emulation software module to perform air quality monitoring operations based on real-time information associated with the vehicle 115. In this example scenario, the vehicle 115 is accelerating on an entrance ramp when entering into a highway. The acceleration may cause fumes to enter the cabin area of the vehicle 115.

In an example scenario, the air quality emulation software module executed by the sensor management system 105 may evaluate images received from the camera 120 and determine that the air quality inside the cabin area has deteriorated as a result of the acceleration of the vehicle 115. The sensor management system 105 may respond to the determination by performing actions such as closing air intake vents and/or activating air-recirculation. In an example scenario, the sensor management system 105 may re-open the air intake vents when the vehicle 115 is decelerating such as, for example, when the vehicle 115 has merged into the traffic on the highway or when moving on an exit ramp to get off the highway.

In other example scenarios, the air quality emulation software module executed by the sensor management system 105 may evaluate other forms of data (in addition to, or in lieu of, evaluating images) such as, for example, data generated by an ultrasonic sensor or a radar sensor provided in the vehicle 115, and/or data generated by the vehicle computer 110 (speed, velocity, braking, fuel consumption, and/or acceleration, etc.).

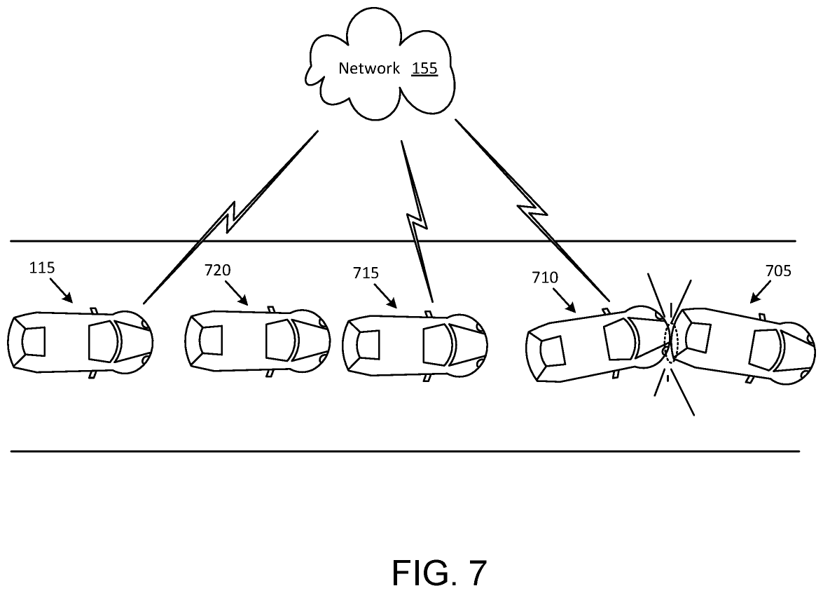

FIG. 7 shows a fifth example scenario where the sensor management system 105 may provide an anti-lock braking system (ABS) system in the vehicle 115, based on an emulation software module received from the computer 160. In this example scenario, the vehicle 115 is traveling on a highway behind a number of vehicles that brake in response to a vehicle 710 rear ending another vehicle 705 up ahead. Various vehicles, such as, for example, the vehicle 710 and the vehicle 715 convey information about the occurrence of the accident to the computer 106 of the sensor management system 105. The computer 106 evaluates the information and responds by using an anti-lock braking system (ABS) emulation software module to provide anti-lock braking of the vehicle 115. The ABS emulation software module is provided to the sensor management system 105 by the computer 160 upon purchase of this feature upgrade due to the vehicle 115 lacking an anti-lock braking system.

The sensor management system 105 may execute the ABS emulation software module to safely bring the vehicle 115 to a halt. In some cases, the sensor management system 105 may perform functions such as ABS braking by using information received from hardware sensors such as, for example, the camera 120. The images provided by the camera 120 provides the sensor management system 105 and/or the vehicle computer 110 information about a separation distance between the vehicle 115 and a vehicle 720 that is braking ahead of the vehicle 115.

In another example scenario, the vehicle 720 (or any other vehicle ahead of the vehicle 115) may lose traction on the road surface (hydroplaning due to water, sliding due to ice buildup, etc.). This information may be wirelessly conveyed to the computer 106 of the sensor management system 105. The computer 106 evaluates the information and responds by using an anti-lock braking system provided by execution of an emulation software module.

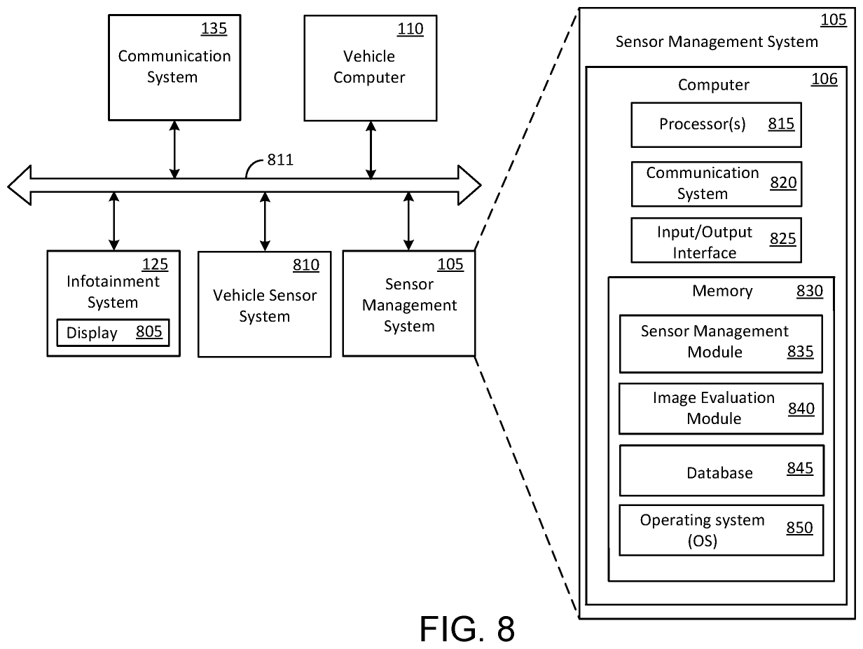

FIG. 8 shows some example components that may be included in the vehicle 115 in accordance with an embodiment of the disclosure. The example components may include the communication system 135, the vehicle computer 110, the infotainment system 125, a vehicle sensor system 810, and the sensor management system 105. The various components are communicatively coupled to each other via one or more buses such as an example bus 811. The bus 811 may be implemented using various wired and/or wireless technologies. For example, the bus 811 can be a vehicle bus that uses a controller area network (CAN) bus protocol, a Media Oriented Systems Transport (MOST) bus protocol, and/or a CAN flexible data (CAN-FD) bus protocol. Some or all portions of the bus 811 may also be implemented using wireless technologies such as Bluetooth®, Bluetooth®, Ultra-Wideband, Wi-Fi, Zigbee®, or near-field-communications (NFC). For example, the bus 811 may include a Bluetooth® communication link that allows the sensor management system 105 and the vehicle sensor system 810 to wirelessly communicate with each other and/or with the vehicle computer 110.

The communication system 135 can include wired and/or wireless communication devices mounted in or on the vehicle 115 in a manner that support various types of communications such as, for example, communications between the sensor management system 105 and the vehicle computer 110. The communication system 135 may also allow the sensor management system 105 to communicate with devices located outside the vehicle 115, such as, for example, computers located in other vehicles (the vehicles are illustrated inside a dashed circle 150) and the computer 160.

In an example implementation, the communication system 135 can include a single wireless communication unit that is coupled to a set of wireless communication nodes. In some cases, the wireless communication nodes can include a Bluetooth® low energy module (BLEM) and/or a Bluetooth® low energy antenna module (BLEAM).

The infotainment system 125 can include a display 805 having a GUI for carrying out various operations. The GUI may be used, for example, to request a software sensor from the computer 160 and/or to make a purchase of a software sensor.

The vehicle sensor system 810 can include various types of sensors, including hardware sensors that are installed in the vehicle 115 either during purchase of the vehicle 115 or at a later time. A few example hardware sensors are the camera 120, the camera 145, and the sun load sensor 205. Other hardware sensors (not shown in figures) can include devices such as, for example, an object detector, a distance sensor, a proximity sensor, an audio sensor, a LIDAR device, a radar device, and/or a sonar device.

The sensor management system 105 may include a processor 815, a communication system 820, an input/output interface 825, and a memory 830. The communication system 820 can include one or more wireless transceivers (BLEMs, for example) that allow the sensor management system 105 to receive various types of items such as, for example an emulation software module and/or a software sensor from the computer 160 (shown in FIG. 1).

The input/output interface 825 can be used to allow various types of signals and information to pass into, or out of, the sensor management system 105. For example, the input/output interface 825 may be used by the sensor management system 105 to receive an emulation software module and/or a software sensor from the computer 160 and also to receive data from various hardware sensors present in the vehicle 115. Thus, the sensor management system 105 can obtain data from the sun load sensor 205 and images from the camera 120 and/or the camera 145. The input/output interface 825 may also be used to receive and/or transmit signals to the vehicle computer 110. An example signal may request the vehicle computer 110 to close one or more air vents in the vehicle 115 and/or to configure a climate control system of the vehicle 115 to recirculate air inside the cabin area of the vehicle 115.

The memory 830, which is one example of a non-transitory computer-readable medium, may be used to store an operating system (OS) 850, a database 845, and various code modules such as a sensor management module 835 and an image evaluation module 840. The code modules are provided in the form of computer-executable instructions that are executed by the processor 815 to enable the sensor management system 105 perform various operations in accordance with the disclosure. The sensor management module 835 can be executed for example, by the processor 815, to perform various operations in accordance with the disclosure. Some example operations can include, for example, making a purchase of a software sensor, downloading a software sensor from the computer 160, rendering a hardware sensor redundant upon receiving and executing the software sensor from the computer 160, and using a software sensor to complement or supplement a functionality provided by one or more hardware sensors in the vehicle 115.

Execution of some of these operations can include the use of the image evaluation module 840 in order to evaluate various types of images such as, for example, images captured by the camera 120 and/or the camera 145. The database 845 may be used to store various types of data such as images, emulation software modules, user preferences, and software sensors,

In the above disclosure, reference has been made to the accompanying drawings, which form a part hereof, which illustrate specific implementations in which the present disclosure may be practiced. It is understood that other implementations may be utilized, and structural changes may be made without departing from the scope of the present disclosure. References in the specification to “one embodiment,” “an embodiment,” “an example embodiment,” etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, one skilled in the art will recognize such feature, structure, or characteristic in connection with other embodiments whether or not explicitly described.

Implementations of the systems, apparatuses, devices, and methods disclosed herein may comprise or utilize one or more devices that include hardware, such as, for example, one or more processors and system memory, as discussed herein. An implementation of the devices, systems, and methods disclosed herein may communicate over a computer network. A “network” is defined as one or more data links that enable the transport of electronic data between computer systems and/or modules and/or other electronic devices. When information is transferred or provided over a network or another communications connection (either hardwired, wireless, or any combination of hardwired or wireless) to a computer, the computer properly views the connection as a transmission medium. Transmission media can include a network and/or data links, which can be used to carry desired program code means in the form of computer-executable instructions or data structures and which can be accessed by a general purpose or special purpose computer. Combinations of the above should also be included within the scope of non-transitory computer-readable media.

Computer-executable instructions comprise, for example, instructions and data which, when executed at a processor, such as the processor 815, cause the processor to perform a certain function or group of functions. The computer-executable instructions may be, for example, binaries, intermediate format instructions such as assembly language, or even source code. Although the subject matter has been described in language specific to structural features and/or methodological acts, it is to be understood that the subject matter defined in the appended claims is not necessarily limited to the described features or acts described above. Rather, the described features and acts are disclosed as example forms of implementing the claims.

A memory device such as the memory 830, can include any one memory element or a combination of volatile memory elements (e.g., random access memory (RAM, such as DRAM, SRAM, SDRAM, etc.)) and non-volatile memory elements (e.g., ROM, hard drive, tape, CDROM, etc.). Moreover, the memory device may incorporate electronic, magnetic, optical, and/or other types of storage media. In the context of this document, a “non-transitory computer-readable medium” can be, for example but not limited to, an electronic, magnetic, optical, electromagnetic, infrared, or semiconductor system, apparatus, or device. More specific examples (a non-exhaustive list) of the computer-readable medium would include the following: a portable computer diskette (magnetic), a random-access memory (RAM) (electronic), a read-only memory (ROM) (electronic), an erasable programmable read-only memory (EPROM, EEPROM, or Flash memory) (electronic), and a portable compact disc read-only memory (CD ROM) (optical). Note that the computer-readable medium could even be paper or another suitable medium upon which the program is printed, since the program can be electronically captured, for instance, via optical scanning of the paper or other medium, then compiled, interpreted or otherwise processed in a suitable manner if necessary, and then stored in a computer memory.

Those skilled in the art will appreciate that the present disclosure may be practiced in network computing environments with many types of computer system configurations, including in-dash vehicle computers, personal computers, desktop computers, laptop computers, message processors, handheld devices, multi-processor systems, microprocessor-based or programmable consumer electronics, network PCs, minicomputers, mainframe computers, mobile telephones, PDAs, tablets, pagers, routers, switches, various storage devices, and the like. The disclosure may also be practiced in distributed system environments where local and remote computer systems, which are linked (either by hardwired data links, wireless data links, or by any combination of hardwired and wireless data links) through a network, both perform tasks. In a distributed system environment, program modules may be located in both the local and remote memory storage devices.

Further, where appropriate, the functions described herein can be performed in one or more of hardware, software, firmware, digital components, or analog components. For example, one or more application specific integrated circuits (ASICs) can be programmed to carry out one or more of the systems and procedures described herein. Certain terms are used throughout the description, and claims refer to particular system components. As one skilled in the art will appreciate, components may be referred to by different names. This document does not intend to distinguish between components that differ in name, but not function.

It should be noted that the sensor embodiments discussed above may comprise computer hardware, software, firmware, or any combination thereof to perform at least a portion of their functions. For example, a sensor may include computer code configured to be executed in one or more processors and may include hardware logic/electrical circuitry controlled by the computer code. These example devices are provided herein for purposes of illustration and are not intended to be limiting. Embodiments of the present disclosure may be implemented in further types of devices, as would be known to persons skilled in the relevant art(s).

At least some embodiments of the present disclosure have been directed to computer program products comprising such logic (e.g., in the form of software) stored on any computer-usable medium. Such software, when executed in one or more data processing devices, causes a device to operate as described herein.

While various embodiments of the present disclosure have been described above, it should be understood that they have been presented by way of example only, and not limitation. It will be apparent to persons skilled in the relevant art that various changes in form and detail can be made therein without departing from the spirit and scope of the present disclosure. Thus, the breadth and scope of the present disclosure should not be limited by any of the above-described example embodiments but should be defined only in accordance with the following claims and their equivalents. The foregoing description has been presented for the purposes of illustration and description. It is not intended to be exhaustive or to limit the present disclosure to the precise form disclosed. Many modifications and variations are possible in light of the above teaching. Further, it should be noted that any or all of the aforementioned alternate implementations may be used in any combination desired to form additional hybrid implementations of the present disclosure. For example, any of the functionality described with respect to a particular device or component may be performed by another device or component. Further, while specific device characteristics have been described, embodiments of the disclosure may relate to numerous other device characteristics. Further, although embodiments have been described in language specific to structural features and/or methodological acts, it is to be understood that the disclosure is not necessarily limited to the specific features or acts described. Rather, the specific features and acts are disclosed as illustrative forms of implementing the embodiments. Conditional language, such as, among others, “can,” “could,” “might,” or “may,” unless specifically stated otherwise, or otherwise understood within the context as used, is generally intended to convey that certain embodiments could include, while other embodiments may not include, certain features, elements, and/or steps. Thus, such conditional language is not generally intended to imply that features, elements, and/or steps are in any way required for one or more embodiments.

That which is claimed is:

1. A method comprising:
determining an availability of a feature upgrade to a first vehicle;
transmitting a request for the feature upgrade;
receiving an emulation software module that provides the feature upgrade based on emulating a first sensor that is unavailable in the first vehicle; and
executing the emulation software module, wherein execution of the emulation software includes processing data from a second sensor of the first vehicle to provide the feature upgrade in the first vehicle, the second sensor being different than the first sensor.

2. The method of claim 1, wherein the second sensor is an original equipment manufacturer (OEM) device of the first vehicle at a time of manufacture of the first vehicle, and wherein the emulation software module emulates at least in part a feature associated with the first sensor based on machine learning applied to data obtained from one or more other vehicles.

3. The method of claim 2, wherein the emulation software module is received from a cloud computer, and wherein the feature upgrade provides a feature function hitherto unavailable in the first vehicle.

4. The method of claim 3, wherein the second sensor is a first type of hardware sensor, and wherein at least a portion of the data obtained from the one or more other vehicles is originated by a first type of hardware sensor.

5. The method of claim 4, wherein the first type of hardware sensor includes a camera.

6. The method of claim 1, wherein the first sensor is a second type of hardware sensor, and the second sensor is a second type of hardware sensor that is different than the first type of hardware sensor.

7. The method of claim 6, wherein the first type of hardware sensor is an air quality sensor and the second type of hardware sensor includes a camera.

8. A method comprising:
receiving, by a cloud computer, a request for a feature upgrade to a first vehicle; and
transmitting, by the cloud computer, to a first vehicle, an emulation software module that provides the feature upgrade based on emulating a first sensor that is unavailable in the first vehicle.

9. The method of claim 8, wherein the emulation software module is executable by a processor of the first vehicle to provide the feature upgrade based on use of a second sensor of the first vehicle that is different than the first sensor.

10. The method of claim 9, wherein the first sensor is a first type of hardware sensor and the second sensor is a second type of hardware sensor that is different than the first type of hardware sensor.

11. The method of claim 10, wherein the first type of hardware sensor is an air quality sensor and the second type of hardware sensor includes a camera.

12. The method of claim 9, wherein the second sensor is an original equipment manufacturer (OEM) device of the first vehicle at a time of manufacture of the first vehicle, and wherein the emulation software module emulates the first sensor based on machine learning applied to sensor data obtained from one or more other vehicles.

13. The method of claim 12, wherein the second sensor is a first type of hardware sensor, and wherein the sensor data obtained from at least one of the one or more other vehicles is from the first type of hardware sensor.

14. The method of claim 12, wherein the request for the feature upgrade is received by the cloud computer from one of the first vehicle, a second processor located outside the first vehicle, or a personal communications device.

15. A vehicle comprising:
a first sensor; and
a first computer comprising:
a memory that stores computer-executable instructions; and
a processor configured to access the memory and execute the computer-executable instructions to perform operations comprising:
transmitting a request for a feature upgrade to the vehicle;
receiving an emulation software module that provides the feature upgrade based on emulating a second sensor that is unavailable on the vehicle; and
executing the emulation software module to provide the feature upgrade based on use of the first sensor.

16. The vehicle of claim 15, wherein the first sensor is an original equipment manufacturer (OEM) device provided in the vehicle at a time of manufacture of the vehicle, and wherein the emulation software module emulates the second sensor based on applying machine learning to data obtained from one or more other vehicles.

17. The vehicle of claim 16, wherein the emulation software module is received from a remote computer.

18. The vehicle of claim 16, wherein the first sensor is a first type of hardware sensor and wherein the sensor data obtained from each of the one or more other vehicles is originated by the first type of hardware sensor.

19. The vehicle of claim 15, wherein the first sensor is a first type of hardware sensor and the second sensor is a second type of hardware sensor that is different than the first type of hardware sensor.

20. The vehicle of claim 19, wherein the second type of hardware sensor is an air quality sensor and the first type of hardware sensor includes a camera.
